(19) United States
(12) Patent Application Publication
(10) Pub. No.: US 2025/0229512 A1
(43) Pub. Date: Jul. 17, 2025

(54) FILM AND METHOD FOR PRODUCING SEMICONDUCTOR PACKAGE

(71) Applicant: AGC Inc., Tokyo (JP)

(72) Inventors: Tetsuo ABE, Tokyo (JP); Ryohei KOGUCHI, Tokyo (JP); Seigo KOTERA, Tokyo (JP)

(73) Assignee: AGC Inc., Tokyo (JP)

(21) Appl. No.: 19/058,451

(22) Filed: Feb. 20, 2025

Related U.S. Application Data
(63) Continuation of application No. PCT/JP2023/031094, filed on Aug. 29, 2023.

(30) Foreign Application Priority Data
Sep. 1, 2022 (JP) 2022-139307

(51) Int. Cl. B32B 27/08; B32B 27/30; B32B 27/32; B32B 27/38; B32B 37/12; H01L 21/56

(52) U.S. Cl. CPC B32B 27/08; B32B 27/304; B32B 27/308; B32B 27/322; B32B 27/38; B32B 37/12; H01L 21/565; B32B 2250/24; B32B 2307/54; B32B 2307/7376; B32B 2457/14

(57) ABSTRACT

This film is a film including a base material, an antistatic layer provided on one surface of the base material, and a release layer provided on a surface of the antistatic layer opposite to the base material, and having an elongation rate of more than 90% and less than 255% as measured by a tensile test at 25° C. and at a speed of 100 mm/min and determined by the following formula:

$$Elongation rate ( \% ) = ( elongation at break ( mm ) ) \times 100 / ( distance between grips before applying tension ( mm ) )$$

The present application is a continuation application of International application No. PCT/JP2023/031094, filed on Aug. 29, 2023, which claims the priority of Japanese Patent Application No. 2022-139307, filed Sep. 1, 2022, the content of which is incorporated herein by reference.

### BACKGROUND OF THE INVENTION

### Field of Invention

The present disclosure relates to a film and a method for producing a semiconductor package.

### Description of Related Art

A semiconductor element is encapsulated in a form of a package and mounted on a substrate in order to be blocked and protected from outside air. A curable resin such as an epoxy resin is used for encapsulating the semiconductor element. Resin encapsulation is performed by placing the semiconductor element in a predetermined place in a mold, filling the mold with a curable resin, and curing the curable resin. A transfer molding method and a compression molding method are generally known as encapsulating methods. In encapsulation of the semiconductor element, a mold release film is often placed on an inner surface of the mold in order to improve releasability of the package from the mold.

In a case of using a mold release film in the production of a semiconductor package, static electricity is generated when peeling off the encapsulated semiconductor package from the film, causing the film to become charged, and the semiconductor package may be damaged by a discharge from the charged film.

In order to prevent the film from becoming charged, Patent Document 1 proposes provision of an antistatic layer between a base material and a release layer.

### CITATION LIST

### Patent Document

Patent Document 1: International Patent Publication No. 2016/125796

### SUMMARY OF INVENTION

As a semiconductor package shape has become more complicated and a height difference of a semiconductor package having an exposed portion has increased in recent years, use of a film that conforms to a complicated shape is increasing. According to the inventors of the present invention, it has been found that when the film described in Patent Document 1 is used to conform to a complicated shape, the release layer and the antistatic layer are easily delaminated. If the release layer and the antistatic layer are delaminated, the release layer is likely to remain attached to the semiconductor package when the encapsulated semiconductor package is peeled off from the film.

The present disclosure provides a film in which a release layer and an antistatic layer are unlikely to be delaminated, and a method for producing a semiconductor package using this film.

### Solution to Problem

The present disclosure provides a film and a method for producing a semiconductor package having the following configurations [1] to [15].

[1] A film including a base material, an antistatic layer provided on one surface of the aforementioned base material, and a release layer provided on a surface of the aforementioned antistatic layer opposite to the aforementioned base material,
wherein the film has an elongation rate of more than 90% and less than 255% as measured by a tensile test at 25° C. and at a speed of 100 mm/min and determined by the following formula:

$$Elongation rate ( \% ) = ( elongation at break ( mm ) ) \times 100 / ( distance between grips before applying tension ( mm ) )$$

[2] The film according to [1] above, wherein the aforementioned base material contains at least one selected from the group consisting of a fluororesin, polymethylpentene, syndiotactic polystyrene, a polycycloolefin, a silicone rubber, a polyester elastomer, polybutylene terephthalate, polyethylene terephthalate, and a polyamide.

[3] The film according to [2] above, wherein the aforementioned fluororesin contains at least one selected from the group consisting of an ethylene-tetrafluoroethylene copolymer, a tetrafluoroethylene-hexafluoropropylene copolymer, a tetrafluoroethylene-perfluoro (alkyl vinyl ether) copolymer, and a tetrafluoroethylene-hexafluoropropylene-vinylidene fluoride copolymer.

[4] The film according to any one of [1] to [3] above, wherein the aforementioned release layer contains a reaction cured product of a hydroxyl group-containing (meth)acrylic polymer and a bifunctional or higher isocyanate compound.

[5] The film according to [4] above, wherein a ratio of isocyanate groups of the aforementioned isocyanate compound with respect to 100 mol % of hydroxyl groups of the aforementioned hydroxyl group-containing (meth)acrylic polymer is from 20 to 115 mol %.

[6] The film according to any one of [1] to [5] above, wherein the aforementioned antistatic layer contains a reaction cured product of a carboxy group-containing (meth)acrylic polymer and at least one selected from the group consisting of a bifunctional or higher aziridine compound and a bifunctional or higher epoxy compound.

[7] The film according to [6] above, wherein a total ratio of aziridine groups of the aforementioned aziridine compound and epoxy groups of the aforementioned epoxy compound with respect to 100 mol % of carboxy groups of the aforementioned carboxy group-containing (meth)acrylic polymer is from 15 to 130 mol %.

[8] The film according to any one of [1] to [7] above, wherein a thickness of the aforementioned base material is from 25 to 250 μm.

[9] The film according to any one of [1] to [8] above, wherein a thickness of the aforementioned release layer is from 0.05 to 3 μm.

[10] The film according to any one of [1] to [9] above, which is a mold release film used in a step of encapsulating a semiconductor element with a curable resin.

[11] A method for producing a semiconductor package, the method including:
placing the film according to any one of [1] to [10] above on an inner surface of a mold;
placing a substrate to which a semiconductor element is fixed in the aforementioned mold on which the aforementioned film is placed;
encapsulating the semiconductor element in the aforementioned mold with a curable resin to produce an encapsulated body; and
releasing the aforementioned encapsulated body from the aforementioned mold.

### Advantageous Effects of Invention

According to the present disclosure, it is possible to provide a film in which a release layer and an antistatic layer are unlikely to be delaminated, and a method for producing a semiconductor package using this film.

### BRIEF DESCRIPTION OF DRAWINGS

FIG. 1 A schematic cross-sectional view showing one embodiment of the present film.

### DETAILED DESCRIPTION OF THE INVENTION

Hereinafter, embodiments of the present disclosure will be described in detail. However, the embodiments of the present disclosure are not limited to the following embodiments. In the following embodiments, constituent elements thereof (including element steps and the like) are not essential unless otherwise specified. The same applies to numerical values and ranges thereof, which do not limit the embodiments of the present disclosure.

In the present disclosure, the term “step” includes not only a step that is independent of other steps, but also a step that cannot be clearly distinguished from other steps, as long as the purpose of this step is achieved.

In the present disclosure, a numerical value range indicated by using “to” includes numerical values described before and after “to” as a minimum value and a maximum value, respectively.

In a numerical value range described in stages in the present disclosure, an upper limit value or a lower limit value described in one numerical value range may be replaced with an upper limit value or a lower limit value of another numerical value range described in stages. Further, in a numerical value range described in the present disclosure, an upper limit value or a lower limit value of the numerical value range may be replaced with a value shown in Examples.

In the present disclosure, each component may contain a plurality of types of corresponding substances. When a plurality of types of substances corresponding to each component are present in a composition, a content ratio or content of each component means a total content ratio or content of the plurality of types of substances present in the composition unless otherwise specified.

When an embodiment is described in the present disclosure with reference to a drawing, configurations of this embodiment are not limited to configurations shown in the drawing. Further, the sizes of members in the drawing are conceptual, and a relative relationship between the sizes of the members is not limited thereto.

In the present disclosure, a “unit” of a polymer means a portion derived from a monomer that exists in the polymer and constitutes the polymer. In addition, one obtained by chemically converting a structure of a certain unit after polymer formation is also referred to as a unit. It should be noted that in some cases, a unit derived from an individual monomer is referred to by a name obtained by adding a “unit” to a name of the monomer.

In the present disclosure, a film and a sheet are referred to as a “film” regardless of a thickness thereof.

In the present disclosure, acrylate and methacrylate are collectively referred to as “(meth)acrylate”, acrylic and methacrylic are collectively referred to as “(meth)acrylic”, and (meth)acryloyl and methacryloyl are collectively referred to as “(meth)acryloyl”.

In the present disclosure, a (meth)acrylic polymer is a polymer having a monomer with a (meth)acryloyl group or a unit based on (meth)acrylic acid. Hereinafter, a monomer with a (meth)acryloyl group or (meth)acrylic acid is also referred to as a “(meth)acrylic monomer”.

### [Film]

A film according to one embodiment of the present disclosure (hereinafter also referred to as the “present film”) is a film including a base material, an antistatic layer provided on one surface of the aforementioned base material, and a release layer provided on a surface of the aforementioned antistatic layer opposite to the aforementioned base material, and having an elongation rate of more than 90% and less than 255% as measured by a tensile test at 23° C. and at a speed of 100 mm/min and determined by the following formula. The elongation rate of the present film is preferably 125% or more and less than 255%, more preferably 175% or more and less than 255%, and particularly preferably 225% or more and less than 255%.

$$Elongation rate ( \% ) = ( elongation at break ( mm ) ) \times 100 / ( distance between grips before applying tension ( mm ) )$$

The “tensile test” can be performed by the method described in the section entitled <Elongation rate> in Examples. More specifically, the film is cut into a strip shape (width: 50 mm, length: 100 mm). This film is clamped and set by grips of a tensile testing machine (for example, RTC-131-A manufactured by Orientec Co., Ltd.). The film is stretched with a distance of 10 mm between grips before applying tension and at a speed of 100 mm/min until the film breaks to measure the elongation at break (mm). The measurement was performed at 23° C.

The inventors of the present invention have found that the present film is less likely to be delaminated between the antistatic layer and the release layer, especially in the production of a semiconductor package having a complex shape.

It is thought that if the elongation rate exceeds 90%, when forming a release layer by applying a coating liquid for release layers on the antistatic layer, the antistatic layer is slightly dissolved by a solvent in the coating liquid, which causes the surface of the antistatic layer to become rough, and the release layer penetrates thereinto, thereby improving the adhesion between the antistatic layer and the release layer.

Further, it is considered that if the elongation rate is less than 255%, the release layer and the antistatic layer each have sufficient cohesive force, and the occurrence of cohesive failure in each layer can be suppressed when the film and the semiconductor package are peeled apart.

The present film only needs to include a base material, an antistatic layer, and a release layer, and other configurations are not particularly limited.

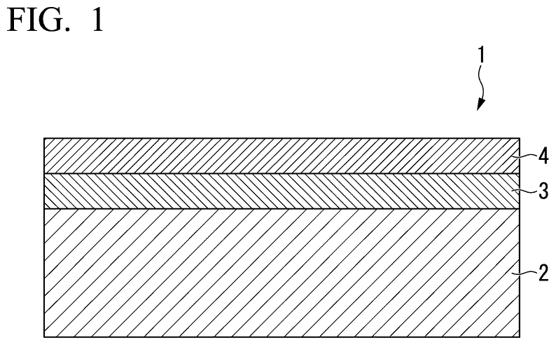

FIG. 1 is a schematic cross-sectional view showing one embodiment of the present film. A film 1 shown in FIG. 1 includes a base material 2, an antistatic layer 3, and a release layer 4 in this order. When the film 1 is used to encapsulate a semiconductor element, the base material 2 is placed so as to be in contact with a mold, and after resin encapsulation, the release layer 4 is brought into contact with an encapsulated body (that is, a semiconductor package in which the semiconductor element is encapsulated). The film 1 may include other layers in addition to the base material 2, the antistatic layer 3, and the release layer 4.

Hereinafter, each constituent element of the present film will be described in detail.

### (Base Material)

A material of the base material is not particularly limited.

The base material typically contains a resin. Examples of the resin include a fluororesin, polymethylpentene, syndiotactic polystyrene, a polycycloolefin, a silicone rubber, a polyester elastomer, polybutylene terephthalate, polyethylene terephthalate, and polyamide.

In one aspect, from the viewpoint of excellent mold releasability of the film, the base material preferably contains a resin having mold releasability (hereinafter, also referred to as a “releasable resin”). The term “releasable resin” means a resin in which a layer composed of this resin has mold releasability. Examples of the releasable resin include a fluororesin, polymethylpentene, syndiotactic polystyrene, a polycycloolefin, a silicone rubber, a polyester elastomer, polybutylene terephthalate, and polyamide. From the viewpoint of excellent mold releasability, heat resistance, strength, and elongation at a high temperature, a fluororesin, polymethylpentene, syndiotactic polystyrene, and a polycycloolefin are preferred, and from the viewpoint of excellent mold releasability, a fluororesin is more preferred.

One type or two or more types of resins may be contained in the base material. It is particularly preferable that the base material is composed of a fluororesin alone. However, even when the base material is composed of a fluororesin alone, this does not prevent the inclusion of resins other than the fluororesin within a range that does not impair the effects of the invention.

The fluororesin is preferably a fluoroolefin polymer from the viewpoint of excellent mold releasability and heat resistance. The fluoroolefin polymer is a polymer having a unit based on a fluoroolefin. The fluoroolefin polymer may further have a unit other than the unit based on a fluoroolefin.

Examples of the fluoroolefin include tetrafluoroethylene (hereinafter also referred to as “TFE”), vinyl fluoride, vinylidene fluoride, trifluoroethylene, hexafluoropropylene (hereinafter also referred to as “HFP”), and chlorotrifluoroethylene. One type of fluoroolefin may be used alone, or two or more types thereof may be used in combination.

Examples of the fluoroolefin polymer include an ethylene-TFE copolymer (hereinafter also referred to as “ETFE”), a TFE-HFP copolymer (hereinafter also referred to as “FEP”), a TFE-perfluoro (alkyl vinyl ether) copolymer, and a TFE-HFP-vinylidene fluoride copolymer. From the viewpoint of mechanical properties, at least one selected from the group consisting of ETFE and FEP is preferred. One type of fluoroolefin polymer may be used alone, or two or more types thereof may be used in combination.

From the viewpoint of large elongation at a high temperature, ETFE is preferred as the fluoroolefin polymer. The ETFE is a copolymer having a unit based on TFE (hereinafter, also referred to as a “TFE unit”) and a unit based on ethylene (hereinafter, also referred to as an “E unit”).

The ETFE is preferably a polymer having a TFE unit, an E unit, and a unit based on a third monomer other than TFE and ethylene. Depending on the type and content of the unit based on the third monomer, the degree of crystallinity of the ETFE can be easily adjusted, and thus a storage elastic modulus or other tensile properties of the base material can be easily adjusted. For example, when the ETFE has the unit based on the third monomer (particularly, a monomer having a fluorine atom), a tensile strength at a high temperature (particularly around 180° C.) tends to be improved.

Examples of the third monomer include a monomer having a fluorine atom and a monomer having no fluorine atoms.

Examples of the monomer having a fluorine atom include the following monomers a1 to a5.

Monomer a1: fluoroolefins having 2 or 3 carbon atoms.

Monomer a2: fluoroalkylethylenes represented by X(CF₂)ₙCY═CH₂ (where X and Y each independently represent a hydrogen atom or a fluorine atom, and n is an integer of 2 to 8).

Monomer a3: fluorovinyl ethers.

Monomer a4: functional group-containing fluorovinyl ethers.

Monomer a5: a fluorine-containing monomer having an aliphatic ring structure.

Specific examples of the monomer a1 include fluoroethylenes (for example, trifluoroethylene, vinylidene fluoride, vinyl fluoride, chlorotrifluoroethylene, and the like) and fluoropropylenes (for example, hexafluoropropylene (HFP), 2-hydropentafluoropropylene, and the like).

As the monomer a2, a monomer in which n is 2 to 6 is preferred, and a monomer in which n is 2 to 4 is more preferred. Further, a monomer in which X is a fluorine atom and Y is a hydrogen atom, that is, (perfluoroalkyl)ethylene is preferred.

Specific examples of the monomer a2 include the following compounds.
CF₃CF₂CH═CH₂,
CF₃CF₂CF₂CF₂CH═CH₂ ((perfluorobutyl)ethylene (hereinafter also referred to as “PFBE”
CF₃CF₂CF₂CF₂CF═CH₂,
CF₂HCF₂CF₂CF═CH₂,
CF₂HCF₂CF₂CF₂CF═CH₂.

Specific examples of the monomer a3 include the following compounds. It should be noted that among the following, a monomer that is a diene is a monomer capable of undergoing cyclopolymerization.
CF₂=CFOCF₃,
CF₂=CFOCF₂CF₃,
CF₂=CFO(CF₂)₂CF₃ (perfluoro (propyl vinyl ether) (hereinafter also referred to as “PPVE”)),
CF₂═CFOCF₂CF(CF₃)O(CF₂)₂CF₃,
CF₂═CFO(CF₂)₃O(CF₂)₂CF₃,
CF₂═CFO(CF₂CF(CF₃)O)₂(CF₂)₂CF₃,
CF₂═CFOCF₂CF(CF₃)O(CF₂)₂CF₃,
CF₂═CFOCF₂CF═CF₂,
CF₂═CFO(CF₂)₂CF═CF₂.

Specific examples of the monomer a4 include the following compounds.
CF₂=CFO(CF₂)₃CO₂CH₃,
CF₂═CFOCF₂CF(CF₃)O(CF₂)₃CO₂CH₃,
CF₂═CFOCF₂CF(CF₃)O(CF₂)₂SO₂F.

Specific examples of the monomer a5 include perfluoro (2,2-dimethyl-1,3-dioxole), 2,2,4-trifluoro-5-trifluoromethoxy-1,3-dioxole, and perfluoro (2-methylene-4-methyl-1,3-dioxolane).

Examples of the monomer having no fluorine atoms include the following monomers b1 to b4.

Monomer b1: olefins.

Monomer b2: vinyl esters.

Monomer b3: vinyl ethers.

Monomer b4: an unsaturated acid anhydride.

Specific examples of the monomer b1 include propylene and isobutene.

Specific examples of the monomer b2 include vinyl acetate.

Specific examples of the monomer b3 include ethyl vinyl ether, butyl vinyl ether, cyclohexyl vinyl ether, and hydroxybutyl vinyl ether.

Specific examples of the monomer b4 include maleic anhydride, itaconic anhydride, citraconic anhydride, and 5-norbornene-2,3-dicarboxylic anhydride.

One type of the third monomer may be used alone, or two or more types thereof may be used in combination.

As the third monomer, from the viewpoint of easy adjustment of the degree of crystallinity and from the viewpoint of excellent tensile strength at a high temperature (particularly around 180° C.), the monomer a2, HFP, PPVE, and vinyl acetate are preferred, HFP, PPVE, CF₃CF₂CH═CH₂, and PFBE are more preferred, and PFBE is particularly preferred. That is, as the ETFE, a copolymer having a TFE unit, an E unit, and a unit based on PFBE (hereinafter, also referred to as a “PFBE unit”) is particularly preferred.

In the ETFE, a molar ratio of the TFE unit with respect to the E unit (TFE unit/E unit) is preferably from 80/20 to 40/60, more preferably from 70/30 to 45/55, and still more preferably from 65/35 to 50/50. When the TFE unit/E unit ratio is within the above range, the ETFE exhibits excellent heat resistance and mechanical strength.

A ratio of the unit based on the third monomer in the ETFE is preferably from 0.01 to 20 mol %, more preferably from 0.10 to 15 mol %, and still more preferably from 0.20 to 10 mol %, with respect to the total (100 mol %) of all units constituting the ETFE. When the ratio of the unit based on the third monomer is within the above range, the ETFE exhibits excellent heat resistance and mechanical strength.

When the unit based on the third monomer includes a PFBE unit, a ratio of the PFBE unit is preferably from 0.5 to 4.0 mol %, more preferably from 0.7 to 3.6 mol %, and still more preferably from 1.0 to 3.6 mol %, with respect to the total (100 mol %) of all units constituting the ETFE. When the ratio of the PFBE unit is within the above range, the tensile strength of the film at a high temperature, particularly at around 180° C., is improved.

The base material may be composed only of the resin, or may further contain other components in addition to the resin. Examples of the other components include a lubricant, an antioxidant, an antistatic agent, a plasticizer, and a mold release agent. From the viewpoint of preventing staining of the mold, it is preferable that the base material does not contain other components.

A thickness of the base material is preferably from 25 to 250 μm, more preferably from 50 to 150 μm, and still more preferably from 75 to 125 μm. When the thickness of the base material is equal to or less than the upper limit value of the above range, the film can be easily deformed and exhibits excellent mold followability. When the thickness of the base material is equal to or more than the lower limit value of the above range, handling of the film, for example, roll-to-roll handling, is easy, and wrinkles are less likely to occur when the film is placed so as to cover a mold cavity while being stretched.

The thickness of the base material can be measured in accordance with an ISO 4591:1992 (JIS K7130:1999) B1 method: a method for measuring the thickness of a sample taken from a plastic film or sheet by a weighing method). Hereinafter, the same applies to the thickness of each layer of the film.

The surface of the base material may have a surface roughness. An arithmetic average roughness Ra of the surface of the base material is preferably from 0.2 to 3.0 μm, and more preferably from 0.5 to 2.5 μm. When the arithmetic average roughness Ra of the surface of the base material is equal to or more than the lower limit value of the above range, the releasability from the mold is further improved. When the arithmetic average roughness Ra of the surface of the base material is equal to or less than the upper limit value of the above range, pinholes are less likely to be formed in the film.

The arithmetic average roughness Ra is measured based on JIS B0601:2013 (ISO 4287:1997, Amd.1:2009). A reference length lr (cutoff value λc) for a roughness curve is 0.8 mm.

The base material may be unstretched or stretched. For example, unstretched polyamide films, biaxially stretched polyamide films, biaxially stretched PET (polyethylene terephthalate) films, biaxially stretched PEN (polyethylene naphthalate) films, biaxially stretched syndiotactic polystyrene films, and unstretched PBT (polybutylene terephthalate) films are commercially available. In addition, polyimide films, polyphenylene sulfide resin films, cross-linked polyethylene films, and the like can be used.

A surface of the base material adjacent to another layer may be subjected to any surface treatment. Examples of the surface treatment include a corona treatment, a plasma treatment, coating with a silane coupling agent, and coating with an adhesive. From the viewpoint of adhesion between the base material and other layers, a corona treatment or a plasma treatment is preferred.

From the viewpoint of adhesion between the base material and the adjacent layer, the wetting tension of the surface of the base material on the antistatic layer side is preferably 20 mN/m or more, more preferably 30 mN/m or more, and particularly preferably 35 mN/m or more. An upper limit of the wetting tension is not particularly limited, and the wetting tension may be 80 mN/m or less.

The base material may be a single layer or may have a multilayer structure. Examples of the multilayer structure include a structure in which a plurality of layers each containing a resin are laminated. In this case, the resins contained in each of the plurality of layers may be the same as or different from each other. From the viewpoints of mold followability, tensile elongation, production costs, and the like, the base material is preferably a single layer. From the viewpoint of film strength, the base material preferably has a multilayer structure.

The multilayer structure may be, for example, a structure in which a layer containing the above-described releasable resin (preferably a fluorine resin) is laminated on a resin film (which may be a film containing only a resin) containing a resin such as a polyester, a polybutylene terephthalate, a polystyrene (preferably syndiotactic), or a polycarbonate, or a structure in which a layer containing a first releasable resin, the resin film, and a layer containing a second releasable resin are laminated in this order. The layer containing the releasable resin and the resin film may be laminated via an adhesive. One surface or both surfaces of each layer containing the releasable resin may be subjected to a corona treatment or a plasma treatment. When the base material has such a multilayer structure, it is preferable that the layer containing the releasable resin is placed on the antistatic layer side. When the base material has such a multilayer structure, it is preferable that the surface on the antistatic layer side of the layer containing the releasable resin and placed on the antistatic layer side is subjected to a corona treatment or a plasma treatment.

### (Antistatic Layer)

The antistatic layer is not particularly limited as long as it is a layer that has an antistatic function. The antistatic layer may be provided on the base material while being adjacent to the base material, or may be provided on the base material via another layer adjacent to the base material.

The antistatic layer may contain an antistatic agent. Examples of the antistatic agent include an ionic liquid, a conductive polymer, and a conductive filler. One type of the antistatic agent may be used alone, or two or more types thereof may be used in combination.

Examples of the ionic liquid include oniums such as pyridinium and imidazolium, and fluorine-based compounds.

The conductive polymer is a polymer in which electrons move and diffuse along a skeleton of the polymer. Examples of the conductive polymer include a polyaniline-based polymer, a polyacetylene-based polymer, a polyparaphenylene-based polymer, a polypyrrole-based polymer, a polythiophene-based polymer, and a polyvinylcarbazole-based polymer.

Examples of the conductive filler include a metal ion conductive salt, a metal compound (for example, a metal oxide, or the like), a filler coated with a metal compound (for example, a metal oxide, or the like), a conductive carbon filler, and a conductive carbon nanotube filler.

Examples of the metal ion conductive salt include a lithium salt compound.

Examples of the metal oxide as a filler and metal oxide that coats a filler include tin oxide, tin-doped indium oxide, antimony-doped tin oxide, phosphorus-doped tin oxide, zinc antimonate, and antimony oxide.

The antistatic agent is preferably at least one selected from the group consisting of a polyaniline polymer, a polyacetylene polymer, a polyparaphenylene polymer, a polypyrrole polymer, a polythiophene polymer, and a polyvinylcarbazole polymer from a viewpoint of excellent heat resistance and conductivity.

The antistatic agent is preferably dispersed in a binder resin. In other words, the antistatic layer is preferably a layer in which an antistatic agent is dispersed in a binder resin.

The binder resin preferably has heat resistance. For example, when the film is used in a step for encapsulating a semiconductor element, it is preferable that the binder resin has heat resistance at about 180° C.

From the viewpoint of excellent heat resistance, the binder resin preferably contains at least one selected from the group consisting of a (meth)acrylic resin, a silicone resin, a urethane resin, a polyester resin, a polyamide resin, a vinyl acetate resin, an ethylene-vinyl acetate copolymer, an ethylene-vinyl alcohol copolymer, a chlorotrifluoroethylene-vinyl alcohol copolymer, and a tetrafluoroethylene-vinyl alcohol copolymer. Among these, from the viewpoint of excellent mechanical strength, it is preferable to be composed of at least one (for example, only a (meth)acrylic resin) selected from the group consisting of a (meth)acrylic resin, a silicone resin, a urethane resin, a polyester resin, a polyamide resin, a vinyl acetate resin, an ethylene-vinyl acetate copolymer, an ethylene-vinyl alcohol copolymer, a chlorotrifluoroethylene-vinyl alcohol copolymer, and a tetrafluoroethylene-vinyl alcohol copolymer. Furthermore, from the viewpoint of excellent heat resistance and dispersibility of the antistatic agent, at least one selected from the group consisting of a polyester resin and a (meth)acrylic resin is preferred.

In the antistatic layer, the binder resin may be crosslinked. When the binder resin is crosslinked, the strength, heat resistance, and solvent resistance are superior as compared with a case where it is not crosslinked.

In one aspect, from the viewpoint of solvent resistance, the antistatic layer preferably contains, as the binder resin, a reaction cured product of a carboxy group-containing (meth)acrylic polymer and at least one selected from the group consisting of a bifunctional or higher aziridine compound (hereinafter also referred to as a “polyfunctional aziridine compound”) and a bifunctional or higher epoxy compound (hereinafter also referred to as a “polyfunctional epoxy compound”). In this case, the carboxy group-containing (meth)acrylic polymer reacts and crosslinks with at least one selected from the group consisting of a polyfunctional aziridine compound and a polyfunctional epoxy compound to become a reaction cured product. The antistatic layer may be a reaction cured product of the carboxy group-containing (meth)acrylic polymer, at least one selected from the group consisting of a polyfunctional aziridine compound and a polyfunctional epoxy compound, and other components.

A ratio of the unit based on the (meth)acrylic monomer with respect to the entire (meth)acrylic polymer is not particularly limited, and is preferably 50% by mass or more, more preferably 60% by mass or more, still more preferably 70% by mass or more, and particularly preferably 80% by mass or more.

A carboxy group included in the carboxy group-containing (meth)acrylic polymer is a crosslinkable functional group that reacts with an aziridine group in the polyfunctional aziridine compound or an epoxy group in the polyfunctional epoxy compound.

An acid value of the carboxy group-containing (meth)acrylic polymer is preferably from 1 to 80 mgKOH/g, more preferably from 1 to 40 mgKOH/g, still more preferably from 1 to 30 mgKOH/g, and particularly preferably from 5 to 30 mgKOH/g. The acid value of the carboxy group-containing (meth)acrylic polymer is an index of the ease of forming crosslinks when reacting with the polyfunctional aziridine compound or the polyfunctional epoxy compound. When the acid value is equal to or less than the above upper limit value, the antistatic layer exhibits excellent extensibility. When the acid value is equal to or more than the above lower limit value, the antistatic layer exhibits excellent adhesion.

When a plurality of types of (meth)acrylic polymers are used in the antistatic layer, the above range is a preferred range for the acid value of this plurality of types of (meth)acrylic polymers as a whole.

The acid value of the (meth)acrylic polymer is measured by a method specified in JIS K0070:1992.

In the carboxy group-containing (meth)acrylic polymer, the carboxy group may be present in a side group, may be present at the end of the main chain, or may be present in both the side chain and the main chain. From the viewpoint of ease of adjusting the content of the carboxy group, it is preferably present at least in a side group.

Examples of the carboxy group-containing (meth)acrylic polymer in which a carboxy group is present in a side group include a (meth)acrylic polymer having a unit based on a carboxy group-containing monomer.

Examples of the carboxy group-containing monomer include a carboxy group-containing (meth)acrylic monomer. Examples of the carboxy group-containing (meth)acrylic monomer include a carboxy group-containing (meth)acrylate and (meth)acrylic acid. Examples of the carboxy group-containing (meth)acrylate include ω-carboxy-polycaprolactone mono(meth)acrylate and mono-2-((meth)acryloyloxy)ethylsuccinic acid. One type of these monomers may be used alone or two or more types thereof may be used in combination.

The carboxy group-containing (meth)acrylic polymer may be composed only of a unit based on a carboxy group-containing monomer, or may further have a unit based on a monomer other than the carboxy group-containing monomer.

Examples of the monomer other than the carboxy group-containing monomer include a (meth)acrylate that does not contain a hydroxyl group and a carboxy group, and a hydroxyl group-containing (meth)acrylate. One type of these monomers may be used alone or two or more types thereof may be used in combination.

Examples of the (meth)acrylate that does not contain a hydroxyl group and a carboxy group include an alkyl (meth)acrylate, cyclohexyl (meth)acrylate, phenyl (meth)acrylate, toluyl (meth)acrylate, benzyl (meth)acrylate, 2-methoxyethyl (meth)acrylate, 3-methoxybutyl (meth)acrylate, glycidyl (meth)acrylate, 2-aminoethyl (meth)acrylate, 3-(methacryloyloxypropyl) trimethoxysilane, trifluoromethylmethyl (meth)acrylate, 2-trifluoromethylethyl (meth)acrylate, 2-perfluoroethylethyl (meth)acrylate, 2-perfluoroethyl-2-perfluorobutylethyl (meth)acrylate, 2-perfluoroethyl (meth)acrylate, perfluoromethyl (meth)acrylate, diperfluoromethylmethyl (meth)acrylate, 2-perfluoromethyl-2-perfluoroethylmethyl (meth)acrylate, 2-perfluorohexylethyl (meth)acrylate, 2-perfluorodecylethyl (meth)acrylate, and 2-perfluorohexadecylethyl (meth)acrylate.

The alkyl (meth)acrylate is preferably a compound in which the alkyl group has 1 to 12 carbon atoms, and examples thereof include methyl (meth)acrylate, ethyl (meth)acrylate, butyl (meth)acrylate, 2-ethylhexyl (meth)acrylate, n-propyl (meth)acrylate, isopropyl (meth)acrylate, isobutyl (meth)acrylate, t-butyl (meth)acrylate, n-pentyl (meth)acrylate, n-hexyl (meth)acrylate, n-heptyl (meth)acrylate, n-octyl (meth)acrylate, nonyl (meth)acrylate, decyl (meth)acrylate, and dodecyl (meth)acrylate.

Examples of the hydroxyl group-containing (meth)acrylate include 2-hydroxyethyl (meth)acrylate, 2-hydroxypropyl (meth)acrylate, 4-hydroxybutyl (meth)acrylate, 1,4-cyclohexanedimethanol monoacrylate, and 2-acryloyloxyethyl-2-hydroxyethyl-phthalic acid.

A mass average molecular weight (hereinafter also referred to as “Mw”) of the carboxy group-containing (meth)acrylic polymer is preferably from 10,000 to 1,000,000, more preferably from 50,000 to 800,000, and still more preferably from 100,000 to 600,000. When Mw is equal to or more than the above lower limit value, the antistatic layer exhibits excellent strength. When Mw is equal to or less than the above upper limit value, the antistatic layer exhibits excellent extensibility.

The Mw of the carboxy group-containing (meth)acrylic polymer is a polystyrene-equivalent value obtained by measurement by gel permeation chromatography using a calibration curve produced using a standard polystyrene sample having a known molecular weight.

A polyfunctional aziridine compound is a compound having two or more aziridine groups in one molecule. The number of aziridine groups in a polyfunctional aziridine compound is preferably 6 or less, and particularly preferably 3 or less, from the viewpoint of obtaining high extensibility without excessively increasing the crosslinking density of the antistatic layer.

Examples of the polyfunctional aziridine compound include 2,2-bishydroxymethylbutanol-tris[3-(1-aziridinyl)propionate], 4,4-bis(ethyleneiminocarbonylamino)diphenylmethane, and trimethylolpropane-tris(β-aziridinyl)propionate. One type of the polyfunctional aziridine compound may be used alone or two or more types thereof may be used in combination.

A commercially available product may be used as the polyfunctional aziridine compound. Examples of the commercially available product include Aracoat CL910 (product name) manufactured by Arakawa Chemical Industries, Ltd., Chemitite (registered trademark) DZ-22E (product name) manufactured by Nippon Shokubai Co., Ltd., and Chemitite (registered trademark) PZ-33 (product name) manufactured by Nippon Shokubai Co., Ltd.

The aziridine equivalent of the polyfunctional aziridine compound is preferably 50 g/eq or more, more preferably 75 g/eq or more, and still more preferably 100 g/eq or more, from the viewpoint of obtaining high extensibility without excessively increasing the crosslinking density of the antistatic layer. From the viewpoint of increasing the strength of the antistatic layer, the aziridine equivalent of the polyfunctional aziridine compound is preferably 300 g/eq or less, more preferably 250 g/eq or less, and still more preferably 200 g/eq. From such a viewpoint, the aziridine equivalent of the polyfunctional aziridine compound is preferably from 50 to 300 g/eq, more preferably from 75 to 250 g/eq, and still more preferably from 100 to 200 g/eq.

A polyfunctional epoxy compound is a compound having two or more epoxy groups in one molecule. The number of epoxy groups in the polyfunctional epoxy compound is preferably 6 or less, and particularly preferably 3 or less, from the viewpoint of obtaining high extensibility without excessively increasing the crosslinking density of the antistatic layer.

Examples of the polyfunctional epoxy compound include N,N,N′,N′-tetraglycidyl-m-xylylenediamine, 1,3-bis(N,N-diglycidylaminomethyl)cyclohexane, resorcinol diglycidyl ether, and glycerol polyglycidyl ether. One type of the epoxy compound may be used alone or two or more types thereof may be used in combination.

A commercially available product may be used as the polyfunctional epoxy compound. Examples of the commercially available product include TETRAD-X (product name) and TETRAD-C(product name) manufactured by Mitsubishi Gas Chemical Company, Inc., and Denacol (registered trademark) EX-201 (product name) and Denacol (registered trademark) EX-313 (product name) manufactured by Nagase ChemteX Corporation.

The epoxy equivalent of the polyfunctional epoxy compound is preferably 30 g/eq or more, more preferably 50 g/eq or more, and still more preferably 90 g/eq or more, from the viewpoint of obtaining high extensibility without excessively increasing the crosslinking density of the antistatic layer. From the viewpoint of increasing the strength of the antistatic layer, the epoxy equivalent of the polyfunctional epoxy compound is preferably 300 g/eq or less, more preferably 200 g/eq or less, still more preferably 150 g/eq or less, and particularly preferably 120 g/eq or less. From such a viewpoint, the epoxy equivalent of the polyfunctional epoxy compound is preferably from 30 to 300 g/eq, more preferably from 50 to 200 g/eq, and still more preferably from 90 to 120 g/eq.

The total ratio of the aziridine groups of the polyfunctional aziridine compound and the epoxy groups of the polyfunctional epoxy compound with respect to 100 mol % of the carboxy groups of the carboxy group-containing (meth)acrylic polymer is preferably from 15 to 130 mol %, more preferably from 15 to 90 mol %, and particularly preferably from 15 to 60 mol %. When the total ratio of the aziridine groups and the epoxy groups is equal to or less than the above upper limit value, the crosslinking density is sufficiently low, and the adhesion between the release layer and the antistatic layer is excellent. When the total ratio of the aziridine groups and the epoxy groups is equal to or more than the above lower limit value, the crosslinking density is sufficiently high, and the antistatic layer exhibits excellent strength.

The antistatic layer may contain other components other than the antistatic agent and the binder resin. Examples of the other components include a lubricant, a coloring agent, and a coupling agent.

Examples of the lubricant include microbeads made of a thermoplastic resin, fumed silica, and polytetrafluoroethylene (PTFE) fine particles.

Examples of the coloring agent include various organic coloring agents and inorganic coloring agents, and more specifically, examples thereof include cobalt blue, red iron oxide, and cyanine blue.

Examples of the coupling agent include a silane coupling agent and a titanate coupling agent.

From the viewpoint of sufficiently exhibiting the antistatic function, the content of the antistatic agent in the antistatic layer is preferably such an amount that the surface resistance value of the film is within a range to be described later.

In one aspect, when the antistatic layer is a layer in which the antistatic agent is dispersed in the binder resin, the content of the antistatic agent may be from 3 to 50% by mass or may be from 5 to 20% by mass with respect to the binder resin. When the content of the antistatic agent is equal to or more than the above lower limit value, the surface resistance value of the film is likely to be within a suitable range. When the content of the antistatic agent is equal to or less than the above upper limit value, the adhesion of the antistatic layer is likely to be favorable.

The content of other components is appropriately set in accordance with the desired surface resistance and strength of the antistatic layer.

A thickness of the antistatic layer is preferably from 0.05 to 3.0 μm, and more preferably from 0.1 to 2.5 μm. When the thickness of the antistatic layer is equal to or more than the above lower limit value, conductivity is exhibited and the antistatic function is excellent. When the thickness of the antistatic layer is equal to or less than the upper limit value of the above range, the stability of the production process including the appearance of the coated surface is excellent.

### (Release Layer)

The release layer may be provided on the antistatic layer while being adjacent to the antistatic layer, or may be provided on the antistatic layer via another layer adjacent to the antistatic layer.

A material of the release layer is not particularly limited.

The release layer may be a layer exhibiting tackiness with respect to other members.

In one aspect, from the viewpoints of heat resistance that can withstand use in a transfer molding process in which the mold and the encapsulation resin are exposed to high temperatures, and compatibility with the antistatic layer, it is preferable that the release layer contains a reaction cured product of a hydroxyl group-containing (meth)acrylic polymer and a bifunctional or higher isocyanate compound (hereinafter also referred to as a “polyfunctional isocyanate compound”). In this case, the hydroxyl group-containing (meth)acrylic polymer reacts and crosslinks with a polyfunctional isocyanate compound to form a reaction cured product. The release layer may be a reaction cured product of a hydroxyl group-containing (meth)acrylic polymer, a polyfunctional isocyanate compound, and other components.

A hydroxyl group included in the hydroxyl group-containing (meth)acrylic polymer is a crosslinkable functional group that reacts with an isocyanate group in the polyfunctional isocyanate compound.

A hydroxyl value of the hydroxyl group-containing (meth)acrylic polymer is preferably 1 mgKOH/g or more, more preferably 29 mgKOH/g or more, and is preferably 100 mgKOH/g or less.

When a plurality of types of (meth)acrylic polymers are used in the release layer, the above range is a preferred range for the hydroxyl value of this plurality of types of (meth)acrylic polymers as a whole.

The hydroxyl value is measured by a method specified in JIS K0070:1992.

The hydroxyl group-containing (meth)acrylic polymer may or may not have a carboxy group. The carboxy group, like the hydroxyl group, is a crosslinkable functional group that reacts with the isocyanate group in the polyfunctional isocyanate compound.

An acid value of the hydroxyl group-containing (meth)acrylic polymer is preferably 100 mgKOH/g or less, more preferably 30 mgKOH/g or less, and may be 0 mgKOH/g.

The crosslinkable functional group equivalent of the hydroxyl group-containing (meth)acrylic polymer, that is, the total equivalent of the hydroxyl group and the carboxyl group, is preferably 500 g/mol or more, more preferably 1,000 g/mol or more, and is preferably 2,000 g/mol or less.

The crosslinkable functional group equivalent corresponds to a molecular weight between crosslinking points, and is a physical property value that governs an elastic modulus after crosslinking, that is, an elastic modulus of the reaction cured product. When the crosslinkable functional group equivalent is equal to or more than the above lower limit value, the elastic modulus of the reaction cured product is reduced, and the release layer exhibits excellent extensibility. When the crosslinkable functional group equivalent is equal to or less than the above upper limit value, the elastic modulus of the reaction cured product is increased, and the release layer exhibits excellent releasability with respect to a resin, an electronic component, and the like. Further, migration of the component of the release layer to a resin, an electronic component, or the like is suppressed.

The crosslinkable functional group equivalent of a hydroxyl group-containing (meth)acrylic polymer can be calculated by dividing the molecular weight of potassium hydroxide (56.1) by the sum of the hydroxyl value and acid value of the hydroxyl group-containing (meth)acrylic polymer, followed by multiplication by 1,000.

In the hydroxyl group-containing (meth)acrylic polymer, the hydroxyl group may be present in a side group, may be present at the end of the main chain, or may be present in both the side chain and the main chain. From the viewpoint of ease of adjusting the content of the hydroxyl group, it is preferably present at least in a side group.

The hydroxyl group-containing (meth)acrylic polymer in which a hydroxyl group is present in a side group is preferably a copolymer having the following unit c1 and unit c2.

Unit c1: a hydroxyl group-containing (meth)acrylate unit.

Unit c2: a unit other than the unit c1.

Examples of the unit c1 include a unit represented by the following Formula 1.

(CH₂—CR¹(COO—R²—OH))— Formula 1
where R¹ is a hydrogen atom or a methyl group, and R² is an alkylene group having 2 to 10 carbon atoms, a cycloalkylene group having 3 to 10 carbon atoms, or —R³—OCO—R⁵—COO—R⁴—, R³ and R⁴ each independently represent an alkylene group having 2 to 10 carbon atoms, and R⁵ is a phenylene group.

R¹ is preferably a hydrogen atom.

The alkylene group represented by R², R³, and R⁴ may be linear or branched.

Specific examples of a monomer to be forming the unit c1 include 2-hydroxyethyl (meth)acrylate, 2-hydroxypropyl (meth)acrylate, 4-hydroxybutyl (meth)acrylate, 1,4-cyclohexanedimethanol monoacrylate, and 2-acryloyloxyethyl-2-hydroxyethyl-phthalic acid. One type of the monomer to be forming the unit c1 may be used alone or two or more types thereof may be used in combination.

From the viewpoint of excellent reactivity of the hydroxyl group, the unit c1 is preferably one in which R² in the above Formula 1 is an alkylene group having 2 to 10 carbon atoms. In other words, a unit based on a hydroxyalkyl (meth)acrylate having a hydroxyalkyl group of 2 to 10 carbon atoms is preferred.

A ratio of the unit c1 with respect to a total (100 mol %) of all units constituting the hydroxyl group-containing (meth)acrylic polymer is preferably 3 mol % or more, and is preferably 40 mol % or less, more preferably 30 mol % or less, and still more preferably 20 mol % or less. When the ratio of the unit c1 is equal to or more than the above lower limit value, the crosslinking density due to the polyfunctional isocyanate compound is sufficiently high, and the release layer exhibits excellent releasability with respect to a resin, an electronic component, and the like. When the ratio of the unit c1 is equal to or less than the above upper limit value, the release layer exhibits excellent adhesion.

The unit c2 is not particularly limited as long as it can be copolymerized with the monomer forming the unit c1. The unit c2 may have a carboxy group, but preferably does not have a reactive group (for example, an amino group) that can react with an isocyanate group other than the carboxy group.

Examples of a monomer to be forming the unit c2 include a macromer having an unsaturated double bond, a (meth)acrylate without a hydroxyl group, (meth)acrylic acid, and acrylonitrile.

Examples of the macromer having an unsaturated double bond include a macromer having a polyoxyalkylene chain such as a (meth)acrylate of a polyethylene glycol monoalkyl ether.

Examples of the (meth)acrylate without a hydroxyl group include an alkyl (meth)acrylate, cyclohexyl (meth)acrylate, phenyl (meth)acrylate, toluyl (meth)acrylate, benzyl (meth)acrylate, 2-methoxyethyl (meth)acrylate, 3-methoxybutyl (meth)acrylate, glycidyl (meth)acrylate, 2-aminoethyl (meth)acrylate, 3-(methacryloyloxypropyl) trimethoxysilane, trifluoromethylmethyl (meth)acrylate, 2-trifluoromethylethyl (meth)acrylate, 2-perfluoroethylethyl (meth)acrylate, 2-perfluoroethyl-2-perfluorobutylethyl (meth)acrylate, 2-perfluoroethyl (meth)acrylate, perfluoromethyl (meth)acrylate, diperfluoromethylmethyl (meth)acrylate, 2-perfluoromethyl-2-perfluoroethylmethyl (meth)acrylate, 2-perfluorohexylethyl (meth)acrylate, 2-perfluorodecylethyl (meth)acrylate, and 2-perfluorohexadecylethyl (meth)acrylate.

The alkyl (meth)acrylate is preferably a compound in which the alkyl group has 1 to 12 carbon atoms, and examples thereof include methyl (meth)acrylate, ethyl (meth)acrylate, butyl (meth)acrylate, 2-ethylhexyl (meth)acrylate, n-propyl (meth)acrylate, isopropyl (meth)acrylate, isobutyl (meth)acrylate, t-butyl (meth)acrylate, n-pentyl (meth)acrylate, n-hexyl (meth)acrylate, n-heptyl (meth)acrylate, n-octyl (meth)acrylate, nonyl (meth)acrylate, decyl (meth)acrylate, and dodecyl (meth)acrylate.

The unit c2 preferably includes at least a unit based on an alkyl (meth)acrylate.

A ratio of the alkyl (meth)acrylate unit with respect to a total (100 mol %) of all units constituting the hydroxyl group-containing (meth)acrylic polymer is preferably 60 mol % or more, more preferably 70 mol % or more, and still more preferably 80 mol % or more, and is preferably 97 mol % or less. When the ratio of the alkyl (meth)acrylate unit is equal to or more than the above lower limit value, a glass transition point, mechanical properties and the like derived from the structure of the alkyl (meth)acrylate are exhibited, and the release layer exhibits excellent mechanical strength and tackiness. When the ratio of the alkyl (meth)acrylate unit is equal to or less than the above upper limit value, the content of the hydroxyl group is sufficient, so that the crosslinking density is increased and a high elastic modulus can be exhibited.

The Mw of the hydroxyl group-containing (meth)acrylic polymer is preferably from 100,000 to 1,200,000, more preferably from 200,000 to 1,000,000, and still more preferably from 200,000 to 700,000. When the Mw is equal to or more than the above lower limit value, the release layer exhibits excellent releasability with respect to a resin, an electronic component, and the like. When the Mw is equal to or less than the above upper limit value, the release layer exhibits excellent adhesion.

The Mw of the hydroxyl group-containing (meth)acrylic polymer is a polystyrene-equivalent value obtained by measurement by gel permeation chromatography using a calibration curve produced using a standard polystyrene sample having a known molecular weight.

A glass transition temperature (Tg) of the hydroxyl group-containing (meth)acrylic polymer is preferably 20° C. or lower, and more preferably 0° C. or lower. When the Tg is equal to or less than the above upper limit value, the release layer exhibits sufficient flexibility even at a low temperature and is unlikely to be delaminated from the base material.

The lower limit value of the Tg is not particularly limited, but within the molecular weight range described above, it is preferably equal to or more than −60° C.

The Tg is a midpoint glass transition temperature measured by differential scanning calorimetry (DSC).

A polyfunctional isocyanate compound is a compound having two or more isocyanate groups in one molecule. The isocyanate group may be protected with a blocking agent.

The number of isocyanate groups in the polyfunctional isocyanate compound is preferably 10 or less, and particularly preferably 3 or less, from the viewpoint of obtaining high extensibility without excessively increasing the crosslinking density of the release layer. The polyfunctional isocyanate compound is most preferably bifunctional or trifunctional.

Examples of the polyfunctional isocyanate compound include hexamethylene diisocyanate (HDI), tolylene diisocyanate (TDI), diphenylmethane diisocyanate (MDI), naphthalene diisocyanate (NDI), tolidine diisocyanate (TODI), isophorone diisocyanate (IPDI), xylene diisocyanate (XDI), triphenylmethane triisocyanate, and tris(isocyanatophenyl)thiophosphate. Further, examples thereof include isocyanurates (that is, trimers) and biurets of these polyfunctional isocyanate compounds, and reaction products of these polyfunctional isocyanate compounds with polyol compounds (for example, adducts, bifunctional prepolymers, trifunctional prepolymers, and the like). Moreover, examples include compounds in which the isocyanate groups of these polyfunctional isocyanate compounds are protected with a blocking agent. Examples of the blocking agent include phenols such as m-cresol and guaiacol, benzenethiol, ethyl acetoacetate, diethyl malonate, and ε-caprolactam.

A bifunctional prepolymer is represented, for example, by OCN—R⁶—NHC(═O)O—R⁷—OC(═O)NH—R⁶—NCO. R⁶ is a residue obtained by removing two isocyanate groups from a diisocyanate compound, and R⁷ is a residue obtained by removing two hydroxyl groups from a diol compound. Examples of the diisocyanate compound include HDI, TDI, MDI, NDI, TODI, IPDI, and XDI, and HDI and IPDI are preferred from the viewpoint of resistance to yellowing. Examples of the diol compound include ethylene glycol and propylene glycol. A commercially available product may be used as the bifunctional prepolymer. Examples of the commercially available product include Duranate (registered trademark) D201 (product name) and D101 manufactured by Asahi Kasei Corporation.

Examples of the trifunctional prepolymer include an isocyanurate of HDI (isocyanurate type HDI), an isocyanurate of TDI (isocyanurate type TDI), an isocyanurate of MDI (isocyanurate type MDI), and a reaction product of a trifunctional polyol and a bifunctional isocyanate. From the viewpoint of resistance to yellowing, an isocyanurate type HDI is preferred.

In one aspect, it is preferable that the polyfunctional isocyanate compound has an isocyanurate ring from the viewpoint that the reaction cured product (that is, the release layer) exhibits a high elastic modulus due to flatness of this ring structure. Examples of the polyfunctional isocyanate compound having an isocyanurate ring include an isocyanurate type HDI, an isocyanurate type TDI, and an isocyanurate type MDI.

A ratio of isocyanate groups of the polyfunctional isocyanate compound with respect to 100 mol % of hydroxyl groups of the hydroxyl group-containing (meth)acrylic polymer is preferably from 20 to 115 mol %, more preferably from 20 to 80 mol %, and particularly preferably from 20 to 70 mol %. When the ratio of the isocyanate groups is equal to or less than the above upper limit value, the crosslinking density is sufficiently low, and the adhesion between the release layer and the antistatic layer is excellent.

When the ratio of the isocyanate groups is equal to or more than the above lower limit value, the crosslinking density is sufficiently high, and the release layer exhibits excellent releasability with respect to a resin, an electronic component, and the like.

In the release layer, the content of the reaction cured product of the hydroxyl group-containing (meth)acrylic polymer and the polyfunctional isocyanate compound is preferably 50% by mass or more, more preferably 60% by mass or more, and still more preferably 70% by mass or more, with respect to the total mass of the release layer.

The release layer may contain other components other than the above reaction cured product. Examples of the other components include a crosslinking catalyst (for example, amines, a metal compound, an acid, and the like), a reinforcing filler, a coloring dye, a pigment, and an antistatic agent.

The crosslinking catalyst may be any substance that functions as a catalyst for a reaction between the hydroxyl group-containing (meth)acrylic copolymer and the polyfunctional isocyanate compound (urethanization reaction), and a general urethanization reaction catalyst can be used. Examples of the crosslinking catalyst include an amine compound such as a tertiary amine, and an organometallic compound such as an organotin compound, an organolead compound, and an organozinc compound.

Examples of the tertiary amine include a trialkylamine, a N,N,N′,N′-tetraalkyldiamine, a N,N-dialkylamino alcohol, triethylenediamine, a morpholine derivative, and a piperazine derivative. Examples of the organotin compound include a dialkyltin oxide, a dialkyltin fatty acid salt, and a stannous fatty acid salt.

The crosslinking catalyst is preferably an organotin compound, and more preferably dioctyltin oxide, dioctyltin dilaurate, dibutyltin laurate, or dibutyltin dilaurate. In addition, a dialkylacetylacetonetin complex catalyst, which is synthesized by reacting a dialkyltin ester and acetylacetone in a solvent and has a structure in which two molecules of acetylacetone are coordinated to one atom of dialkyltin, can be used.

The amount of the crosslinking catalyst used is preferably from 0.01 to 0.5 parts by mass with respect to 100 parts by mass of the hydroxyl group-containing (meth)acrylic polymer.

A thickness of the release layer is preferably from 0.05 μm to 3.0 μm, more preferably from 0.05 μm to 2.5 μm, and still more preferably from 0.05 μm to 2.0 μm. When the thickness of the release layer is equal to or more than the above lower limit value, the releasability is excellent. When the thickness of the release layer is equal to or less than the above upper limit value, the function of the antistatic layer is sufficiently exhibited, and the surface resistance value of the film on the release layer side is low.

### (Other Layers)

The film may or may not include a layer other than the base material, the antistatic layer, and the release layer. Examples of the other layers include a gas barrier layer and a colored layer. One type of these layers may be used alone or two or more types thereof may be used in combination.

### (Method for Producing Film)

The present film is produced, for example, by the following method.

A coating liquid for the antistatic layer, which contains a composition for the antistatic layer and a liquid medium, is applied onto one side of the base material and dried to form an antistatic layer. A coating liquid for the release layer, which contains a composition for the release layer and a liquid medium, is applied onto the surface of the formed antistatic layer opposite to the base material and dried to form a release layer. Any other layer may be formed. In the formation of each layer, heating may be performed in order to promote curing. The heating may be performed each time each layer is formed, or may be performed after forming a plurality of layers.

The composition for the antistatic layer preferably contains an antistatic agent, a carboxy group-containing (meth)acrylic polymer, and at least one selected from the group consisting of a polyfunctional aziridine compound and a polyfunctional epoxy compound. It should be noted that the composition for the antistatic layer does not contain a liquid medium.

The composition for the release layer preferably contains a hydroxyl group-containing (meth)acrylic polymer and a polyfunctional isocyanate compound. It should be noted that the composition for the release layer does not contain a liquid medium.

### (Surface Resistance Value of Film)

A surface resistance value of the present film is not particularly limited, and may be 10¹⁷Ω/□ or less, preferably 10¹¹Ω/□ or less, more preferably 10¹⁰Ω/□ or less, and still more preferably 10⁹Ω/□ or less. A lower limit of the surface resistance value is not particularly limited.

The surface resistance value of the present film is measured in accordance with IEC 60093:1980: guarded electrode system with an applied voltage of 500 V and an application time of 1 minute. As a measuring device, for example, an ultra high resistance meter R8340 (Advantec Toyo Kaisha, Ltd.) can be used.

### (Use of Film)

The present film is also useful, for example, as a mold release film used in a step of encapsulating a semiconductor element with a curable resin, and as a surface protection film for a semiconductor element, a solar cell module, and the like. Among them, it is particularly useful as a mold release film used in a step of producing a semiconductor package having a complicated shape, for example, an encapsulated body in which a part of an electronic component is exposed from the above resin.

### [Method for Producing Semiconductor Package]

In one aspect, a method for producing a semiconductor package includes:
placing the present film on an inner surface of a mold;
placing a substrate to which a semiconductor element is fixed in the aforementioned mold in which the present film is placed;
encapsulating the semiconductor element in the aforementioned mold with a curable resin to produce an encapsulated body; and
releasing the aforementioned encapsulated body from the aforementioned mold.

Examples of the semiconductor package include: an integrated circuit in which semiconductor elements such as a transistor and a diode are integrated; and a light-emitting diode including a light-emitting element.

A package shape of the integrated circuit may cover the entire integrated circuit, or may cover a part of the integrated circuit, that is, may expose a part of the integrated circuit. Specific examples thereof include a single in-line package (SIP), a zigzag in-line package (ZIP), a dual in-line package (DIP), a small outline J-leaded package (SOJ), a small outline non-leaded package (SON), a small outline I-leaded package (SOI), a small outline F-leaded package (SOF), a quad flat package (QFP), a quad flat J-leaded package (QFJ), a quad flat non-leaded package (QFN), a quad flat F-leaded package (QFF), a pin grid array (PGA), a land grid array (LGA), a ball grid array (BGA), a dual tape carrier package (DTP), a quad tape carrier package (QTP), a chip size package/chip scale package (CSP), a wafer level CSP (WL-CSP), a leadless lead frame package (LLP), a dual flatpack no-leaded package (DFN), a multi chip package (MCP), a multi chip module (MCM), a system in a package (SiP), a package on a package (POP), a package in a package (PiP), a quad in-line package (QIP or QUIP), a ceramic flat package (CFP), a lead less chip carrier (LLCC), a fan out wafer level package (FOWLP), a chip on board (COB), a chip on film (COF), a chip on glass (COG) and a surface vertical package (SVP).

From the viewpoint of productivity, the semiconductor package is preferably produced through collective encapsulation and singulation, and examples thereof include an integrated circuit whose encapsulation method is a molded array packaging (MAP) method or a wafer level packaging (WL) method.

The curable resin is preferably a thermosetting resin such as an epoxy resin and a silicone resin, and more preferably an epoxy resin.

In one aspect, the semiconductor package may or may not include an electronic component such as a source electrode and a seal glass in addition to the semiconductor element. Further, a part of this semiconductor element and the electronic component such as a source electrode and a seal glass may be exposed from the resin.

As a method for producing the above semiconductor package, a known production method can be adopted, with the exception that the present film is used. For example, a transfer molding method may be used as a method for encapsulating the semiconductor element, and a known transfer molding device can be used as the device used in this case. The production conditions can also be the same as those in the known method for producing a semiconductor package.

### Examples

Next, embodiment of the present disclosure will be more specifically described with reference to Examples, but the embodiments of the present disclosure are not limited to these Examples. In the following Cases, Cases 2 to 4, 7, 8, 10 to 13, 16, 17, and 19 are Examples, and Cases 1, 5, 6, 9, 14, 15, and 18 are Comparative Examples. The term “part(s)” means “part(s) by mass”.

### Evaluation Method

### <Elongation Rate>

A film was cut into a strip shape (width: 50 mm, length: 100 mm). This film was clamped and set between grips of a tensile testing machine (for example, RTC-131-A manufactured by Orientec Co., Ltd.). The film was stretched with a distance of 10 mm between grips before applying tension and at a speed of 100 mm/min until the film broke to measure the elongation at break (mm). The measurement was performed at 23° C. The elongation rate was determined from the measurement results using the following formula. The results are shown in Table 1.

$$Elongation rate ( \% ) = ( elongation at break ( mm ) ) \times 100 / ( distance between grips before applying tension ( mm ) )$$

### <Surface Resistance Value>

The surface resistance value (Ω/□) of the film on the release layer side was measured in accordance with IEC 60093:1980: guarded electrode system. The measurement was performed using an ultra high resistance meter R8340 (Advantec Toyo Kaisha, Ltd.) as a measurement device with an applied voltage of 500 V and an application time of 1 minute.

### <Preparation of Epoxy Resin Composition for Mold Releasability Test>

The following materials were pulverized and mixed for 5 minutes using a super mixer to prepare an epoxy resin composition for an encapsulation test.
8 parts of phenylene skeleton-containing phenol aralkyl-type epoxy resin (softening point: 58° C., epoxy equivalent: 277),
2 parts of bisphenol A-type epoxy resin (melting point: 45° C., epoxy equivalent: 172),
2 parts of phenylene skeleton-containing phenol aralkyl resin (softening point: 65° C., hydroxyl equivalent: 165),
2 parts of phenol novolac resin (softening point: 80° C., hydroxyl equivalent: 105),
0.2 parts of curing accelerator (triphenylphosphine),
84 parts of inorganic filler (fused spherical silica with a median diameter of 16 μm),
0.1 parts of carnauba wax,
0.3 parts of carbon black,
0.2 parts of coupling agent (3-glycidoxypropyltrimethoxysilane).

A cured product of the epoxy resin composition had a glass transition temperature of 135° C., a storage elastic modulus at 130° C. of 6 GPa, and a storage elastic modulus at 180° C. of 1 GPa.

### <Mold Releasability Test>

A mold releasability test was performed by the following procedure using the films of each example as mold release films, the epoxy resin composition for mold releasability test described above as a curable resin, and an encapsulating device (G-LINE Manual System, transfer molding device manufactured by Apic Yamada Corporation). A 70 mm×230 mm copper lead frame to which a semiconductor element had been fixed was used.

Five protrusions having a size of 5 mm×5 mm were provided at equal intervals on an upper die of a mold provided with upper and lower dies, and a film roll having a width of 190 mm was set in a roll-to-roll manner. The film was placed so that the base material was on the side with the five protrusions. After placing the lead frame to which the semiconductor element had been fixed on the lower die, the film was vacuum sucked onto the upper die, the mold was clamped, and the curable resin was poured thereinto. At this time, in order to expose a portion of the semiconductor element from the resin, the surface of the film on the release layer side and the semiconductor element placed in the lower die were brought into direct contact on the five protrusion parts of the upper die, and encapsulation was performed such that an encapsulation resin was filled therearound. After applying pressure for 5 minutes, the mold was opened and an encapsulated body was taken out.

After the mold releasability test, the appearance of each peeled surface of the release layer of the mold release film and a cured product of the curable resin were visually confirmed and evaluated in accordance with the following criteria.

A: A state in which the release layer was not adhered to the surface of the cured product of the curable resin, and there was no peeling or destruction of the release layer.

B-1: A state in which the release layer was adhered to the surface of the cured product of the curable resin, and no residue of the release layer was present on the mold release film side. It is considered that both the antistatic layer and the release layer were excessively cured, resulting in low interlayer adhesion and peeling at the interface.

B-2: A state in which the release layer was adhered to the surface of the cured product of the curable resin, and no residue of the release layer was present on the mold release film side. It is considered that the difference in shrinkage rate occurred due to the amount of curing agent reactive group with respect to each main agent of the antistatic layer and the release layer being large or small, resulting in peeling at the interface.

C: A state in which the release layer adheres to the surface of the cured product of the curable resin, and the residue of the release layer is present on the mold release film side. It is considered that although the amount of curing agent reactive group with respect to the main agent in both the antistatic layer and the release layer is extremely small, resulting in favorable interlayer adhesion and no interfacial delamination, the mold releasability was not exhibited and cohesive failure occurred within the release layer.

### (Materials Used)

### <Base Material>

ETFE film: Fluon (registered trademark) ETFE C-88AXP (manufactured by AGC Inc.) was fed into an extruder equipped with a T-die, and taken up between a pressing roller with an uneven surface and a metal roller with a mirror surface to produce a film having a thickness of 100 μm. A temperature of the extruder and the T-die was 320° C., and a temperature of the pressing roller and the metal roller was 100° C. Ra of a surface of the obtained film was 2.0 μm on a pressing roller side and 0.2 μm on a mirror surface side. A corona treatment was applied to the mirror surface side so that a wetting tension based on ISO8296:1987 (JIS K6768:1999) was 40 mN/m or more. The obtained film was wound into a roll shape.

### <Materials for Antistatic Layer>

Main agent 1: Aracoat (registered trademark) AS601D (manufactured by Arakawa Chemical Industries, Ltd.), solid content: 3.4% by mass, conductive polythiophene: 0.4% by mass, carboxy group-containing (meth)acrylic polymer: 3.0% by mass.

Curing agent 1-1: Aracoat CL910 (manufactured by Arakawa Chemical Industries, Ltd.), solid content: 10% by mass, trifunctional aziridine compound (2,2-bishydroxymethylbutanol-tris[3-(1-aziridinyl)propionate], aziridine equivalent: 142 g/eq.

Curing agent 1-2: Chemitite (registered trademark) DZ-22E (manufactured by Nippon Shokubai Co., Ltd.), solid content: 25% by mass, bifunctional aziridine compound (4,4-bis(ethyleneiminocarbonylamino)diphenylmethane), aziridine equivalent: 165 g/eq.

### <Materials for Release Layer>

Main agent 2: Nissetsu (registered trademark) KP2562 (manufactured by Nippon Carbide Industries Co., Inc.), solid content: 35% by mass, hydroxyl group-containing (meth)acrylic polymer (hydroxyl value: 70 mg KOH/g, crosslinkable functional group equivalent: 801 g/mol).

Curing agent 2-1: Nissetsu CK157 (manufactured by Nippon Carbide Industries Co., Inc.), solid content: 100% by mass, trifunctional isocyanate compound (isocyanurate-type hexamethylene diisocyanate), NCO content: 21% by mass.

Curing agent 2-2: Duranate (registered trademark) D201 (manufactured by Asahi Kasei Corporation), solid content: 100% by mass, bifunctional isocyanate compound (bifunctional prepolymer-type hexamethylene diisocyanate: OCN—R—NHC(═O)O—R′—OC(═O)NH—R—NCO), NCO content: 15.8% by mass.

### (Case 1)

10 parts of the main agent 1, 1 part of the curing agent 1-1, and methanol were mixed to prepare a coating liquid for the antistatic layer. The amount of methanol added was set to an amount such that the solid content of the coating liquid for the antistatic layer was 2% by mass.

The obtained coating liquid for the antistatic layer was coated onto the surface of the base material on the side that had been subjected to a corona treatment using a gravure coater, and dried to form an antistatic layer having a thickness of 0.8 μm. The coating was performed by a direct gravure method using a 100 mm (diameter)×250 mm (width) roller with a grid 150 (mesh)-40 μm (depth) as a gravure plate. The drying was performed at 55° C. for 1 minute through a roll support drying oven with an air volume of 19 m/sec.

Subsequently, 100 parts of the main agent 2, 6 parts of the curing agent 2-1, and ethyl acetate were mixed to prepare a coating liquid for the release layer. The amount of ethyl acetate added was set to an amount such that the solid content of the coating liquid for the release layer was 25% by mass.

The obtained coating liquid for the release layer was coated onto the surface of the base material on the side where the antistatic layer was formed using a gravure coater, and dried to form a release layer having a thickness of 0.8 μm. The coating was performed by a direct gravure method using a 100 mm (diameter)×250 mm (width) roller with a grid 150 (mesh)-40 μm (depth) as a gravure plate. The drying was performed at 100° C. for 1 minute through a roll support drying oven with an air volume of 19 m/sec. After that, curing was performed at 40° C. for 120 hours to obtain a film.

### (Cases 2 to 19)

Films were produced in the same manner as in Case 1, with the exception that the amounts of the main agents and the types and amounts of the curing agents added to each of the coating liquid for the antistatic layer and the coating liquid for the release layer were changed as shown in Tables 1 to 2.

The elongation rates, surface resistance values, and results of mold releasability tests of the obtained films are shown in Tables 1 to 2.

In Tables 1 to 2, “aziridine groups with respect to 100 mol % COOH” is the ratio of aziridine groups of the aziridine compound with respect to 100 mol % of carboxy groups of the carboxy group-containing (meth)acrylic polymer. “NCO with respect to 100 mol % OH” is the ratio of isocyanate groups of the isocyanate compound with respect to 100 mol % of hydroxyl groups of the hydroxyl group-containing (meth)acrylic polymer. “10\hat{ }8” for the surface resistance value indicates 108.

TABLE 1

| Case | | 1 | 2 | 3 | 4 | 5 | 6 | 7 | 8 | 9 | 10 |
|---|---|---|---|---|---|---|---|---|---|---|---|
| Antistatic | Main agent 1 | 10 | 10 | 10 | 10 | 10 | 10 | 10 | 10 | 10 | 10 |
| layer | (parts) | | | | | | | | | | |
| | Curing agent | 1 | 0.7 | 0.5 | 0.3 | 1.2 | 1 | 1 | 1 | 1 | 1 |
| | 1-1 (parts) | | | | | | | | | | |
| | Curing agent | — | — | — | — | — | — | — | — | — | — |
| | 1-2 (parts) | | | | | | | | | | |
| | Aziridine | 112 | 79 | 56 | 34 | 135 | 112 | 112 | 112 | 112 | 112 |
| | groups with | | | | | | | | | | |
| | respect to 100 | | | | | | | | | | |
| | mol % COOH | | | | | | | | | | |
| | (mol %) | | | | | | | | | | |
| Release | Main agent 2 | 100 | 100 | 100 | 100 | 100 | 100 | 100 | 100 | 100 | 100 |
| layer | (parts) | | | | | | | | | | |
| | Curing agent | 6 | 6 | 6 | 6 | 6 | 7 | 4 | 2 | 1 | 3 |
| | 2-1 (parts) | | | | | | | | | | |
| | Curing agent | — | — | — | — | — | — | — | — | — | — |
| | 2-2 (parts) | | | | | | | | | | |
| | NCO with | 103 | 103 | 103 | 103 | 103 | 120 | 69 | 34 | 17 | 52 |
| | respect to 100 | | | | | | | | | | |
| | mol % OH | | | | | | | | | | |
| | (mol %) | | | | | | | | | | |
| Physical | Elongation rate | 90% | 125% | 150% | 175% | 55% | 50% | 125% | 150% | 90% | 140% |
| properties | Surface | 10\hat{ }8 | 10\hat{ }8 | 10\hat{ }8 | 10\hat{ }8 | 10\hat{ }8 | 10\hat{ }8 | 10\hat{ }8 | 10\hat{ }8 | 10\hat{ }8 | 10\hat{ }8 |
| | resistance | | | | | | | | | | |
| | value (Ω/□) | | | | | | | | | | |
| Evaluation | Mold | B-1 | A | A | A | B-1 | B-1 | A | A | B-2 | A |
| | releasability | | | | | | | | | | |
| | test | | | | | | | | | | |

TABLE 2

| Case | | 11 | 12 | 13 | 14 | 15 | 16 | 17 | 18 | 19 |
|---|---|---|---|---|---|---|---|---|---|---|
| Antistatic | Main agent 1 | 10 | 10 | 10 | 10 | 10 | 10 | 10 | 10 | 10 |
| layer | (parts) | | | | | | | | | |
| | Curing agent | 0.5 | 0.3 | 0.13 | 0.7 | 0.15 | 0.15 | — | — | 0.5 |
| | 1-1 (parts) | | | | | | | | | |
| | Curing agent | — | — | — | — | — | — | 0.2 | 0.6 | — |
| | 1-2 (parts) | | | | | | | | | |
| | Aziridine | 56 | 34 | 15 | 79 | 17 | 17 | 50 | 150 | 45 |
| | groups with | | | | | | | | | |
| | respect to 100 | | | | | | | | | |
| | mol % COOH | | | | | | | | | |
| | (mol %) | | | | | | | | | |
| Release | Main agent 2 | 100 | 100 | 100 | 100 | 100 | — | 100 | 100 | 100 |
| layer | (parts) | | | | | | | | | |
| | Curing agent | 4 | 2 | 1.2 | 1 | 4 | — | 2 | 2 | 3 |
| | 2-1 (parts) | | | | | | | | | |
| | Curing agent | — | — | — | — | — | 5 | — | — | — |
| | 2-2 (parts) | | | | | | | | | |
| | NCO with | 69 | 34 | 21 | 17 | 69 | 65 | 34 | 34 | 52 |
| | respect to 100 | | | | | | | | | |
| | mol % OH | | | | | | | | | |
| | (mol %) | | | | | | | | | |
| Physical | Elongation rate | 200% | 225% | 250% | 260% | 255% | 250% | 225% | 85% | 210% |
| properties | Surface | 10\hat{ }8 | 10\hat{ }8 | 10\hat{ }8 | 10\hat{ }8 | 10\hat{ }8 | 10\hat{ }8 | 10\hat{ }8 | 10\hat{ }8 | 10\hat{ }8 |
| | resistance | | | | | | | | | |
| | value (Ω/□) | | | | | | | | | |
| Evaluation | Mold | A | A | A | C | B-2 | A | A | B-2 | A |
| | releasability | | | | | | | | | |
| | test | | | | | | | | | |

As shown in Tables 1 and 2, the results of the mold releasability tests were A for the films of Cases 2 to 4, 7, 8, 10 to 13, 16, 17, and 19, which had elongation rates of more than 90% and less than 255%.

### INDUSTRIAL APPLICABILITY

In the film of the present disclosure, the release layer and the antistatic layer are unlikely to be delaminated when encapsulating a semiconductor element with a curable resin. By using the film of the present disclosure as a mold release film, a semiconductor package such as an integrated circuit in which semiconductor elements such as a transistor and a diode and electronic components such as a source electrode and sealing glass are integrated can be produced. The film of the present disclosure can also be used as a protective film when processing, transporting, and storing a semiconductor element, a solar cell module, and the like.

### REFERENCE SIGNS LIST

1 Film
2 Base material
3 Antistatic layer
4 Release layer

What is claimed is:

1. A film comprising a base material, an antistatic layer provided on one surface of said base material, and a release layer provided on a surface of said antistatic layer opposite to said base material,
wherein the film has an elongation rate of more than 90% and less than 255% as measured by a tensile test at 25° C. and at a speed of 100 mm/min and determined by the following formula:
$$Elongation rate ( \% ) = ( elongation at break ( mm ) ) \times 100 / ( distance between grips before applying tension ( mm ) )$$

2. The film according to claim 1,
wherein said base material comprises at least one selected from the group consisting of a fluororesin, polymethylpentene, syndiotactic polystyrene, a polycycloolefin, a silicone rubber, a polyester elastomer, polybutylene terephthalate, polyethylene terephthalate, and a polyamide.

3. The film according to claim 2,
wherein said fluororesin comprises at least one selected from the group consisting of an ethylene-tetrafluoroethylene copolymer, a tetrafluoroethylene-hexafluoropropylene copolymer, a tetrafluoroethylene-perfluoro (alkyl vinyl ether) copolymer, and a tetrafluoroethylene-hexafluoropropylene-vinylidene fluoride copolymer.

4. The film according to claim 1,
wherein said release layer comprises a reaction cured product of a hydroxyl group-containing (meth)acrylic polymer and a bifunctional or higher isocyanate compound.

5. The film according to claim 4,
wherein a ratio of isocyanate groups of said isocyanate compound with respect to 100 mol % of hydroxyl groups of said hydroxyl group-containing (meth)acrylic polymer is from 20 to 115 mol %.

6. The film according to claim 1,
wherein said antistatic layer comprises a reaction cured product of a carboxy group-containing (meth)acrylic polymer and at least one selected from the group consisting of a bifunctional or higher aziridine compound and a bifunctional or higher epoxy compound.

7. The film according to claim 6,
wherein a total ratio of aziridine groups of said aziridine compound and epoxy groups of said epoxy compound with respect to 100 mol % of carboxy groups of said carboxy group-containing (meth)acrylic polymer is from 15 to 130 mol %.

8. The film according to claim 1, wherein a thickness of said base material is from 25 to 250 μm.

9. The film according to claim 1, wherein a thickness of said release layer is from 0.05 to 3 μm.

10. The film according to claim 1, which is a mold release film used in a step of encapsulating a semiconductor element with a curable resin.

11. A method for producing a semiconductor package, the method comprising:
placing the film according to claim 1 on an inner surface of a mold;
placing a substrate to which a semiconductor element is fixed in said mold on which said film is placed;
encapsulating the semiconductor element in said mold with a curable resin to produce an encapsulated body; and
releasing said encapsulated body from said mold.

12. The film according to claim 2,
wherein said release layer comprises a reaction cured product of a hydroxyl group-containing (meth)acrylic polymer and a bifunctional or higher isocyanate compound.

13. The film according to claim 12,
wherein a ratio of isocyanate groups of said isocyanate compound with respect to 100 mol % of hydroxyl groups of said hydroxyl group-containing (meth)acrylic polymer is from 20 to 115 mol %.

14. The film according to claim 2,
wherein said antistatic layer comprises a reaction cured product of a carboxy group-containing (meth)acrylic polymer and at least one selected from the group consisting of a bifunctional or higher aziridine compound and a bifunctional or higher epoxy compound.

15. The film according to claim 14,
wherein a total ratio of aziridine groups of said aziridine compound and epoxy groups of said epoxy compound with respect to 100 mol % of carboxy groups of said carboxy group-containing (meth)acrylic polymer is from 15 to 130 mol %.

16. The film according to claim 2, wherein a thickness of said base material is from 25 to 250 μm.

17. The film according to claim 2, wherein a thickness of said release layer is from 0.05 to 3μ m.

18. The film according to claim 2, which is a mold release film used in a step of encapsulating a semiconductor element with a curable resin.

19. A method for producing a semiconductor package, the method comprising:
placing the film according to claim 2 on an inner surface of a mold;
placing a substrate to which a semiconductor element is fixed in said mold on which said film is placed;
encapsulating the semiconductor element in said mold with a curable resin to produce an encapsulated body; and
releasing said encapsulated body from said mold.
